(19) United States
(12) Patent Application Publication
(10) Pub. No.: US 2025/0338434 A1
(43) Pub. Date: Oct. 30, 2025

(54) COOLING DEVICE AND COLD PLATE

(71) Applicant: NIDEC CORPORATION, Kyoto (JP)

(72) Inventor: Takaya OKUNO, Kyoto (JP)

(21) Appl. No.: 19/184,018

(22) Filed: Apr. 21, 2025

(30) Foreign Application Priority Data
Apr. 25, 2024 (JP) 2024-071769

(51) Int. Cl. H05K 7/20

(52) U.S. Cl. CPC H05K 7/20254; H05K 7/20272

(57) ABSTRACT

A cooling device includes a first and second cold plate, and first, second, third, and fourth pipes. The first cold plate includes first and second openings, and a first flow path continuous with each of the first and second openings. The first pipe is connected to the first opening. The second pipe is connected to the second opening. The second cold plate includes third and fourth openings, and a second flow path continuous with each of the third and fourth openings. The third pipe is connected to the third opening. The fourth pipe is connected to the fourth opening. The first and second openings are spaced apart from each other in the first direction. The fourth pipe extends between the first and second openings and in a second direction intersecting the first direction.

### CROSS-REFERENCE TO RELATED APPLICATIONS

The present application claims priority under 35 U.S.C. § 119 to Japanese Patent Application No. 2024-071769, filed on Apr. 25, 2024, the entire contents of which are hereby incorporated herein by reference.

### 1. Field of the Invention

The present disclosure relates to cooling devices and cold plates.

### 2. Background

A liquid cooling module is disclosed as an example of a cooling device according to the related art. The pipe connected to the inlet of the liquid cooling module on the right side in the width direction acts as an introduction pipe. The refrigerant is introduced from the outside of the electronic device into the liquid cooling module on the right through the introduction pipe.

The pipe connected to the outlet of the liquid cooling module on the left acts as a discharge pipe. The liquid refrigerant inside the liquid cooling module on the left side is discharged to the outside of the electronic device through the discharge pipe.

The inlet of the liquid cooling module on the right side and the outlet of the liquid cooling module on the left side are also connected by a pipe, and the pipe acts as a transfer pipe.

The cooling device has a problem that piping becomes complicated when the number of objects to be cooled increases.

### SUMMARY

An example embodiment of a cooling device of the present disclosure includes a first cold plate, a first pipe, a second pipe, a second cold plate, a third pipe, and a fourth pipe. The first cold plate includes a first opening, a second opening, and a first flow path continuous with each of the first opening and the second opening. The first pipe is connected to the first opening. The second pipe is connected to the second opening. The second cold plate includes a third opening, a fourth opening, and a second flow path continuous with each of the third opening and the fourth opening. The third pipe is connected to the third opening. The fourth pipe is connected to the fourth opening. The first opening and the second opening are spaced apart from each other in the first direction. The fourth pipe extends between the first opening and the second opening and in a second direction intersecting the first direction.

An example embodiment of a cold plate of the present disclosure includes a main body, three or more openings, and a flow path. The main body includes a cooler that is brought into thermal contact with an object to be cooled. The three or more openings are provided in a portion other than the cooler in the main body. The flow path is continuous with each of the three or more openings.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view illustrating a cooling device 100 (first example embodiment of the present disclosure) in a use state.

FIG. 2 is a perspective view of the cooling device 100 in a use state illustrated in FIG. 1 as viewed from another direction.

FIG. 3 is a perspective view illustrating openings 11A to 11I formed in cold plates 1A to 1D illustrated in FIG. 1.

FIG. 4 is a side view of the cooling device 100 illustrated in FIG. 3 as viewed from one side X1 in the X direction.

FIG. 5 is a cross-sectional view of the cooling device 100 taken along line V-V illustrated in FIG. 4 as viewed from one side Z1 in the Z direction.

FIG. 6 is a cross-sectional view of a cross section of the cooling device 100 taken along line VI-VI illustrated in FIG. 4 as viewed from one side Z1 in the Z direction.

FIG. 7 is a perspective view illustrating a cooling device 100 according to a first modification of an example embodiment of the present disclosure.

FIG. 8 is a perspective view illustrating a cooling device 100 according to a second example embodiment of the present disclosure in a use state.

FIG. 9 is a perspective view illustrating openings 11A to 11T formed in cold plates 1A to 1I illustrated in FIG. 8.

### DETAILED DESCRIPTION

Hereinafter, a cooling device 100 according to each example embodiment of the present disclosure will be described with reference to the drawings. In the drawings, the same or corresponding parts are denoted by the same reference numeral and description thereof will not be repeated.

The term “connection” means “connection through which a fluid can flow”.

The term “thermally contacting” means “directly thermally contacting” or “thermally contacting (via something)”.

The term “intersecting” includes lines, surfaces, or lines and surfaces intersecting each other at a right angle and intersecting each other at a non-right angle within a range or a slight difference consistent with the purpose of the present disclosure. The slight difference includes tolerance, error, and the like.

The term “pipe” means a pipe (pipe or tube), a joint (also called a coupling), or a combination of pipes and joints. The pipe is, for example, a metal pipe or a resin pipe.

Hereinafter, each example embodiment of the present disclosure will be described.

In each drawing, a Z direction, an X direction, and a Y direction intersecting each other are illustrated.

The Z direction is defined based on a state in which the cooling device 100 is installed on an object to be cooled (to be described later) in a usable manner (hereinafter, also referred to as a “use state”). The Z direction is a vertical direction of the cooling device 100. The X direction is, for example, a direction in which the openings 11A and 11B are arranged.

One side and the other side in the Z direction are also referred to as one side Z1 in the Z direction and the other side Z2 in the Z direction. In the present example embodiment, the one side Z1 in the Z direction and the other side Z2 in the Z direction are an upward direction and a downward direction of the cooling device 100 in a use state.

One side and the other side in the X direction are also referred to as one side X1 in the X direction and the other side X2 in the X direction. In the present example embodiment, the one side X1 in the X direction is a direction in which the opening 11B is positioned as viewed from the opening 11A in the cooling device 100 in a use state. The other side X2 in the X direction is a direction opposite to the one side X1 in the X direction.

One side and the other side in the Y direction are also referred to as one side Y1 in the Y direction and the other side Y2 in the Y direction. In the present example embodiment, one side Y1 in the Y direction is a direction in which the cold plate 1C is positioned as viewed from the opening 11A in the cooling device 100 in a use state. The other side Y2 in the Y direction is a direction opposite to the one side Y1 in the Y direction.

Hereinafter, the cooling device 100 according to the first example embodiment will be described.

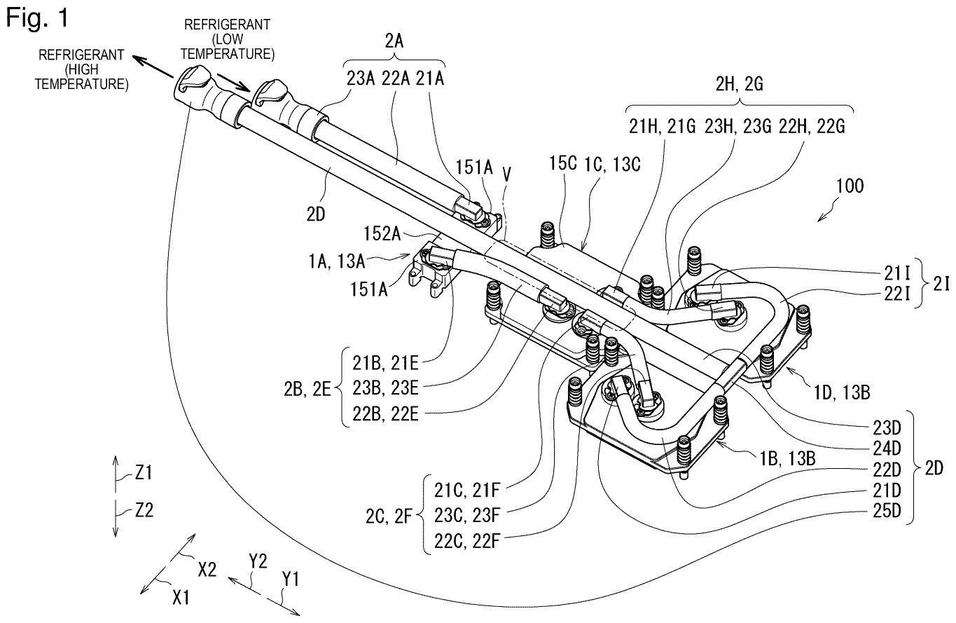

In FIG. 1, the cooling device 100 includes cold plates 1A to 1D and pipes 2A to 2I.

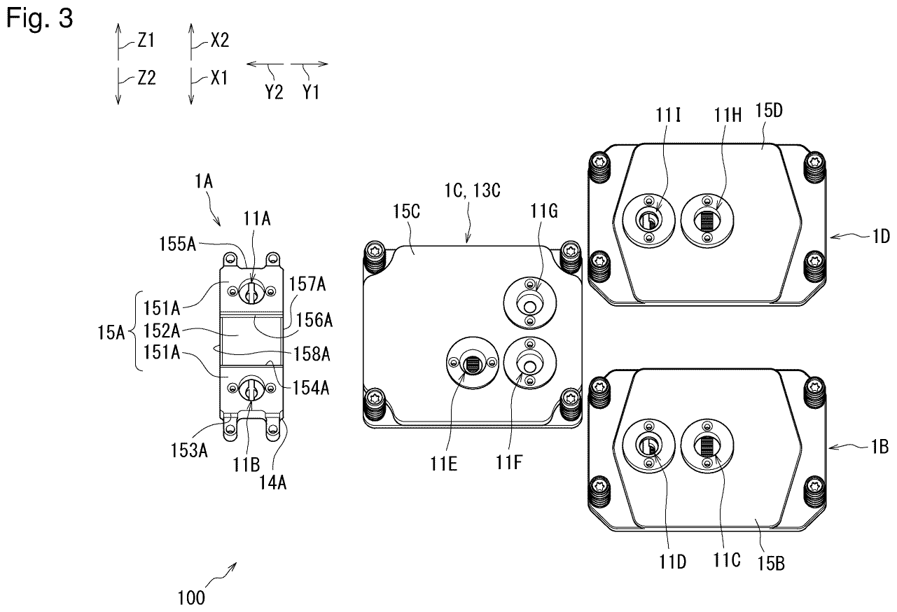

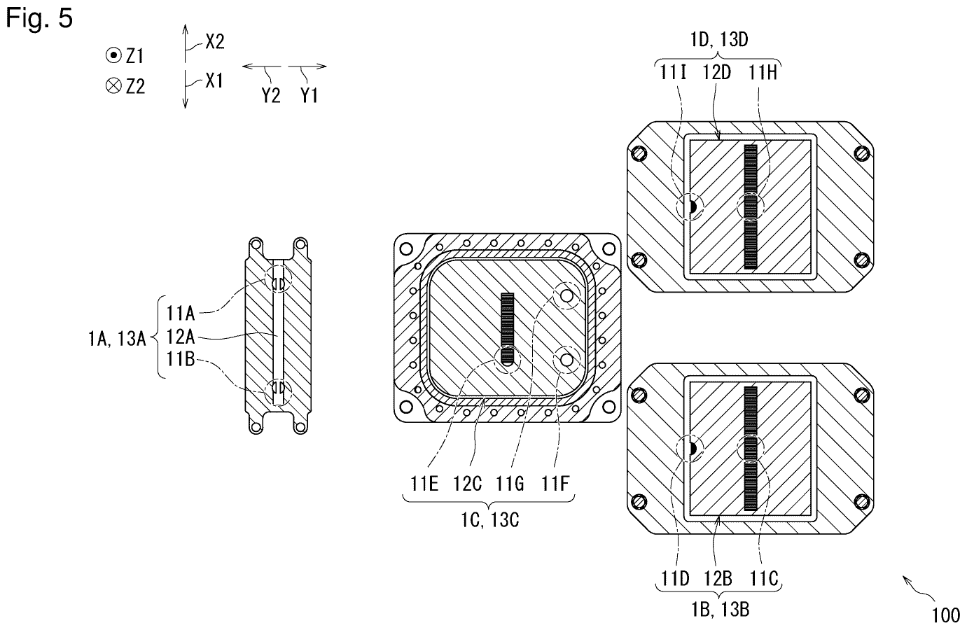

As illustrated in FIGS. 3 and 5, the cold plate 1A has openings 11A and 11B and a flow path 12 A. In FIG. 5, the openings 11A and 11B are indicated by dashed imaginary lines. The flow path 12A is continuous with each of the openings 11A and 11B. The cold plate 1A is an example of a “first cold plate” according to the present disclosure. The openings 11A and 11B are examples of a “first opening” and a “second opening” of the present disclosure. The flow path 12A is an example of a “first flow path” in the present disclosure.

As illustrated in FIG. 1, the pipes 2A and 2B are connected to the openings 11A and 11B (see FIG. 5), respectively. The pipes 2A and 2B are examples of a “first pipe” and a “second pipe” of the present disclosure.

As illustrated in FIGS. 3, 5, and 6, the cold plate 1B includes openings 11C and 11D and a flow path 12B. The flow path 12B is continuous with each of the openings 11C and 11D. The cold plate 1B is an example of a “second cold plate” according to the present disclosure. The openings 11C and 11D are examples of a “third opening” and a “fourth opening” of the present disclosure. The flow path 12B is an example of a “second flow path” in the present disclosure.

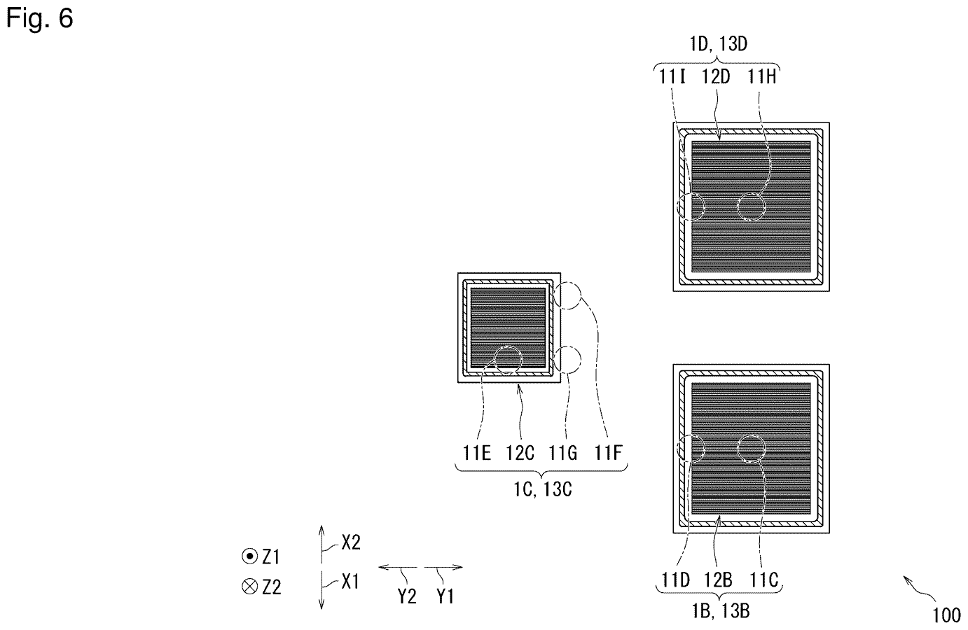

As illustrated in FIG. 1, the pipes 2C and 2D are connected to the openings 11C and 11D (see FIGS. 5 and 6), respectively. The pipes 2C and 2D are examples of a “third pipe” and a “fourth pipe” of the present disclosure.

As illustrated in FIG. 5, the openings 11A and 11B are located apart from each other in the X direction. The pipe 2D extends between the openings 11A and 11B and extends in the Y direction. As a result, the piping is not complicated. Specifically, since the pipe 2D is aligned with both the pipes 2A and 2B in the X direction, the piping (that is, attachment of the pipes 2A, 2B, and 2D) does not become complicated. The X direction and the Y direction are examples of a “first direction” and a “second direction” of the present disclosure.

As illustrated in FIGS. 5 and 6, the cold plate 1C includes openings 11E to 11G and a flow path 12C. The flow path 12C is continuous with each of the openings 11E to 11G. The cold plate 1C is an example of a “third cold plate” of the present disclosure. The openings 11E, 11F, and 11G are examples of a “fifth opening”, a “sixth opening”, and a “seventh opening” of the present disclosure. The flow path 12C is an example of a “third flow path” in the present disclosure.

The pipes 2E to 2G are connected to the openings 11E to 11G, respectively. The pipe 2G is an example of a “fifth pipe” of the present disclosure.

As illustrated in FIGS. 5 and 6, the cold plate 1D includes openings 11H and 11I and a flow path 12D. The flow path 12D is continuous with each of the openings 11H and 11I. The cold plate 1D is an example of a “fourth cold plate” according to the present disclosure. The openings 11H and 11I are examples of an “eighth opening” and a “ninth opening” of the present disclosure. The flow path 12D is an example of a “fourth flow path” in the present disclosure.

The pipe 2H is connected to the opening 11H. The pipe 2I is connected to the opening 11I and the pipe 2D. The pipe 2I is an example of a “sixth pipe” of the present disclosure. This shortens the total length of the pipes. Specifically, even in a case where the number of cold plates is four, since the pipe 2I is connected to the pipe 2D, the total length of the pipes (pipes 2A to 2I) is shortened.

As illustrated in an imaginary line of an oval V in FIG. 1, at least a part of the pipe 2D extends along at least one of the pipes 2B, 2C, and 2E. As a result, the movement of the pipe 2D is restricted. This suppresses complication of routing of the pipe.

The openings 11E to 11G are located apart from each other in at least one of the X direction and the Y direction. The pipe 2D extends between two selected openings from among the openings 11E to 11G. As a result, the movement of the pipe 2D is restricted. This suppresses complication of routing of the pipe.

As illustrated in FIGS. 5 and 6, the opening 11C is located farther from the opening 11F than the opening 11D. The opening 11H is located farther from the opening 11G than the opening 11I. As a result, the pipes 2C and 2G can be gently bent. As a result, loads applied to the pipes 2C and 2G are suppressed.

In FIG. 1, in the cooling device 100 in use, the cooling-temperature refrigerant first flows into the cold plate 1A among the cold plates 1A to 1D. Specifically, the refrigerant flows into the cold plate 1A from the opening 11A through the pipe 2A. The refrigerant flows out of the opening 11B from the opening 11A through the flow path 12A. While the refrigerant flows through the flow path 12A, heat is transferred from an object to be cooled in thermal contact with a cooler 14A of the cold plate 1A to the refrigerant flowing through the flow path 12A. As a result, the object to be cooled is cooled.

The refrigerant flowing out of the cold plate 1A flows into the cold plate 1C from the opening 11C through the pipes 2B and 2E. The refrigerant flows out of the openings 11F and 11G through the flow path 12C from the opening 11E. In the course of the refrigerant flowing through the flow path 12C, the object to be cooled that is in thermal contact with the cooler 14C is cooled.

The refrigerant flowing out of the opening 11F flows into the cold plate 1B from the opening 11C through the pipes 2C and 2F. The refrigerant flows out of the opening 11D from the opening 11C through the flow path 12B. In the course of the refrigerant flowing through the flow path 12B, the object to be cooled that is in thermal contact with the cooler 14B is cooled.

The refrigerant flowing out of the opening 11G flows into the cold plate 1D from the opening 11H through the pipes 2G and 2H. The refrigerant flows out of the opening 11I through the flow path 12D from the opening 11H. In the course of the refrigerant flowing through the flow path 12D, the object to be cooled that is in thermal contact with the cooler 14D is cooled.

The high-temperature refrigerant flowing out of the opening 11D circulates in the pipe 2D. The high-temperature refrigerant flowing out of the opening 11I merges with the refrigerant in the pipe 2D through the pipe 2I. The refrigerant flowing through the pipe 2D flows out of the cooling device 100.

The refrigerant is, for example, a coolant. Examples of the coolant include antifreeze liquid and pure water. A typical example of antifreeze liquid is an ethylene glycol aqueous solution or a propylene glycol aqueous solution. The refrigerant is not limited to a liquid refrigerant, and may be a gas refrigerant.

Hereinafter, the configuration of the cooling device 100 will be described in more detail.

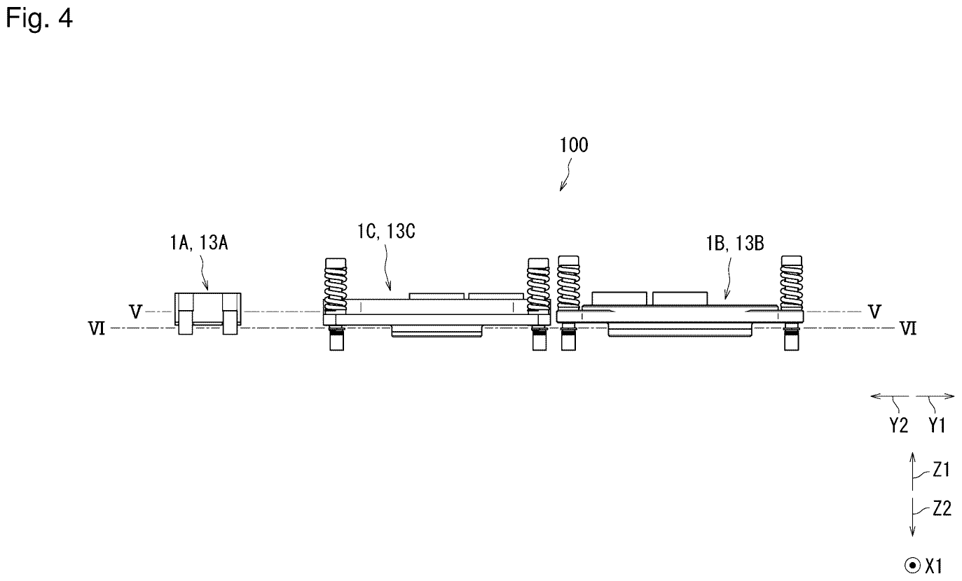

In FIGS. 1 to 6, the cold plates 1A to 1D include main bodies 13A to 13D. The outer shape of the main bodies 13A to 13D is a substantially rectangular parallelepiped thin in the Z direction.

Each of the main bodies 13A to 13D is made of a high thermal conductivity material. Examples of this type of material include metals such as copper and aluminum. In addition, each of the main bodies 13A to 13D can be manufactured by fine ceramics containing aluminum nitride or silicon carbide.

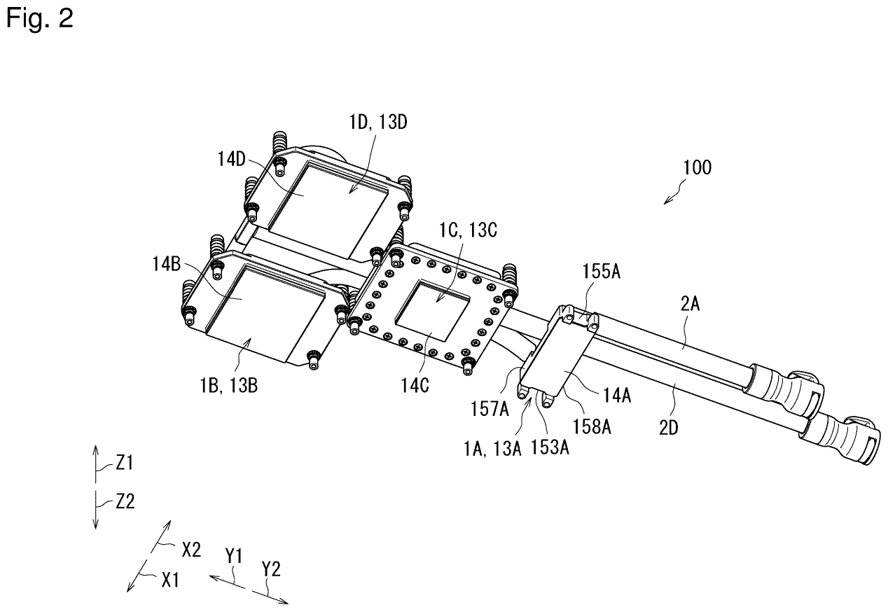

As illustrated in FIG. 2, the main bodies 13A to 13D include coolers 14A to 14D. Each of the coolers 14A to 14D is a surface facing the other side Z2 in the Z direction when the cooling device 100 is in a use state. The coolers 14A to 14D can be in thermal contact with an object to be cooled (not illustrated).

The object to be cooled is, for example, a heat source. The heat source is an electronic component or an electronic device. The electronic component is a component constituting electronic equipment, and includes, for example, a central processing unit (so-called CPU), an electrolytic capacitor, a power semiconductor module, or a printed circuit board. The electronic component operates by power supply and generates heat. The electronic equipment is a rack mounted server or a blade server. The electronic equipment may also be a projector, a personal computer, or a display.

As illustrated in FIG. 3, the main body 13A has a surface 15A. The planar shape of the surface 15A is substantially rectangular. The surface 15A is separated from the cooler 14A toward the one side Z1 in the Z direction. The surface 15A has two protruding portions 151A and a recessed portion 152A.

Both of the two protruding portions 151A extend in the X direction and the Y direction. One of the two protruding portions 151A is a portion on the surface 15A between an end 153A on the one side X1 in the X direction and a portion 154A away from the end 153A toward the other side X2 in the X direction.

The other of the two protruding portions 151A is a portion on the surface 15A between an end 155A on the other side X2 in the X direction and a portion 156A away from the end 155A toward the one side X1 in the X direction. The opening 11A and the opening 11B are formed in the two protruding portions 151A, respectively.

The recessed portion 152A is a portion between the two protruding portions 151A on the surface 15A, and extends in the X direction and the Y direction. The recessed portion 152A is located on the other side Z2 in the Z direction with respect to the two protruding portions 151A between an end 157A on the one side Y1 in the Y direction and an end 158A on the other side Y2 in the Y direction.

As illustrated in FIG. 1, the pipe 2D extends through the recessed portion 152A between the two protruding portions 151A. Therefore, the pipe 2D is prevented from being displaced in the X direction.

The pipe 2A includes an elbow 21A, a pipe 22A made of resin, and a quick coupling 23A. One port of the elbow 21A is connected to the opening 11A. One end of the pipe 22A is connected to the other port of the elbow 21A. The other end of the pipe 22A is connected to a port of the quick coupling 23A.

The pipe 2B includes elbows 21B and 22B and a pipe 23B made of resin. Ports on one sides of the elbows 21B and 22B are connected to the openings 11B and 11E respectively. The pipe 23B connects the other ports of the elbows 21B and 22B.

As illustrated in FIGS. 5 and 6, the volume of the flow path 12A is smaller than the volume of each of the flow paths 12B to 12D. As a result, the difference between the refrigerant temperature at the time of flowing into the flow path 12A and the refrigerant temperature at the time of flowing out of the flow path 12A can be made relatively small. Accordingly, cooling capacity of the cold plates 1B to 1D does not excessively decrease.

In FIGS. 1 to 6, the main body 13C is located on the one side Y1 in the Y direction with respect to the main body 13A. As illustrated in FIG. 3, the main body 13C has a surface 15C facing the same direction as the surface 15A and substantially parallel to the surface 15A. The openings 11E to 11G are formed in the surface 15C. The opening 11E is located closest to the main body 13A among the openings 11E to 11G. The opening 11F is formed at a position separated from the opening 11E by a distance on the one side Y1 in the Y direction. The opening 11G is located at the other side X2 in the X direction with respect to the opening 11F.

As illustrated in FIG. 1, the pipe 2E is common to the pipe 2B in the first example embodiment. The pipe 2E includes elbows 21E and 22E and a pipe 23E that are the same as the elbow 21B and 22B and the pipe 23B. When another cold plate different from the cold plates 1A to 1D is connected between the openings 11B and 11E, the elbows 21E and 22E and the pipe 23E are different from the elbows 21B and 22B and the pipe 23B, respectively.

In FIGS. 1 to 6, the main body 13B is located on the one side Y1 in the Y direction with respect to the main body 13C. As illustrated in FIG. 3, the main body 13C has a surface 15B facing the same direction as the surface 15A and substantially parallel to the surface 15A. The openings 11C and 11D are formed in the surface 15B. The opening 11C is farther from the opening 11F than the opening 11D.

The pipe 2C includes elbows 21C and 22C and a pipe 23C made of resin. Ports on one sides of the elbows 21C and 22C are connected to the openings 11F and 11C. The pipe 23C connects ports on the other sides of the elbows 21C and 22C to each other.

In FIGS. 1 to 6, the main body 13D is located on the one side Y1 in the Y direction with respect to the main body 13C and on the other side X2 in the X direction with respect to the main body 13B. As illustrated in FIG. 3, the main body 13D has a surface 15D that faces the same direction as the surface 15A and is substantially parallel to the surface 15A. The openings 11H and 11I are formed in the surface 15D. The opening 11H is farther from the opening 11G than the opening 11I.

The pipe 2G includes elbows 21G and 22G and a pipe 23G made of resin. Ports on one side of the elbows 21G and 22G are connected to the openings 11G and 11H. The pipe 23C connects ports on the other sides of the elbows 21C and 22C to each other.

As illustrated in FIG. 1, the pipe 2F is common to the pipe 2C in the first example embodiment. The pipe 2F includes elbows 21F and 22F and a pipe 23F that are the same as the elbows 21C and 22C and the pipe 23C. When another cold plate different from the cold plates 1A to 1D is connected between the openings 11F and 11C, the elbows 21F and 22F and the pipe 23F are different from the elbows 21C and 22C and the pipe 23C, respectively.

As illustrated in FIG. 1, the pipe 2H is common to the pipe 2G in the first example embodiment. The pipe 2H includes elbows 21H and 22H and a pipe 23H that are the same as the elbows 21G 22G and the pipe 23G. When another cold plate different from the cold plates 1A to 1D is connected between the openings 11G and 11H, the elbows 21H and 22H and the pipe 23H are different from the elbows 21G and 22G and the pipe 23G, respectively.

The pipe 2D includes an elbow 21D, pipes 22D and 23D made of resin, a tee joint 24D, and a quick coupling 25D. One port of the elbow 21D is connected to the opening 11D. One end of the pipe 22D is connected to the other port of the elbow 21D. The other end of the pipe 22D is connected to a first port of the tee joint 24D. One end of the pipe 23D is connected to a second port of the tee joint 24D. The other end of the pipe 23D is connected to a port of the quick coupling 25D.

The pipe 2I includes an elbow 21I and a pipe 22I made of resin. One port of the elbow 21I is connected to the opening 11I. One end of the pipe 22I is connected to the other port of the elbow 21I. The other end of the pipe 22I is connected to a third port of the tee joint 24D.

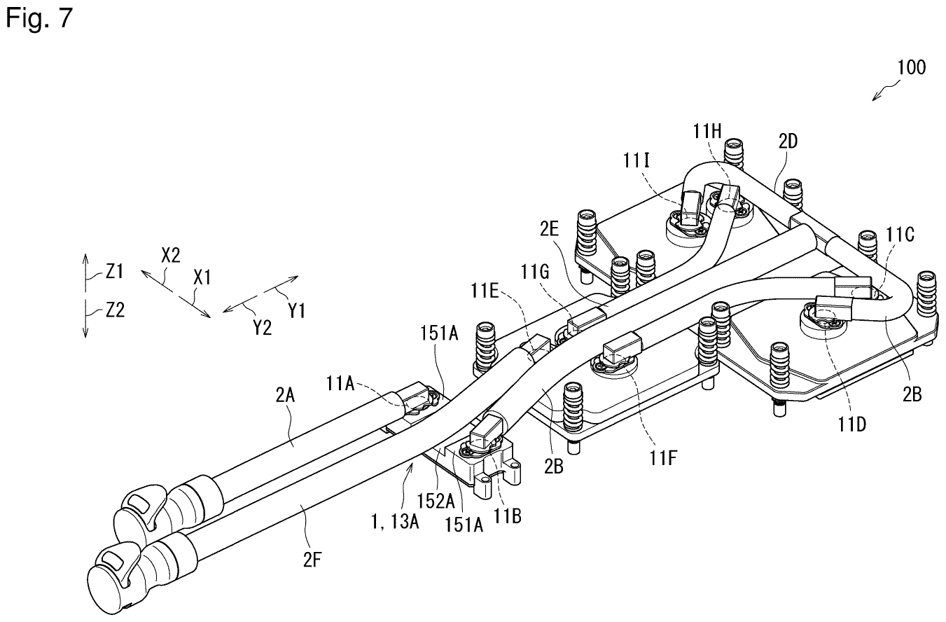

As illustrated in FIG. 7, the cooling device 100 is different from the first example embodiment in the following points. That is, the pipe 2B connects the openings 11B and 11D. The pipe 2C connects the openings 11C and 11F. The pipe 2D branches from the pipe 2C and is connected to the opening 11I. The pipe 2E connects the openings 11H and 11G. The pipe 2F is connected to the opening 11E, extends through the recessed portion 152A, and extends in the Y direction. In FIG. 7, the openings 11A to 11I are indicated by dashed imaginary lines.

Hereinafter, a cooling device 100 according to a second example embodiment will be described.

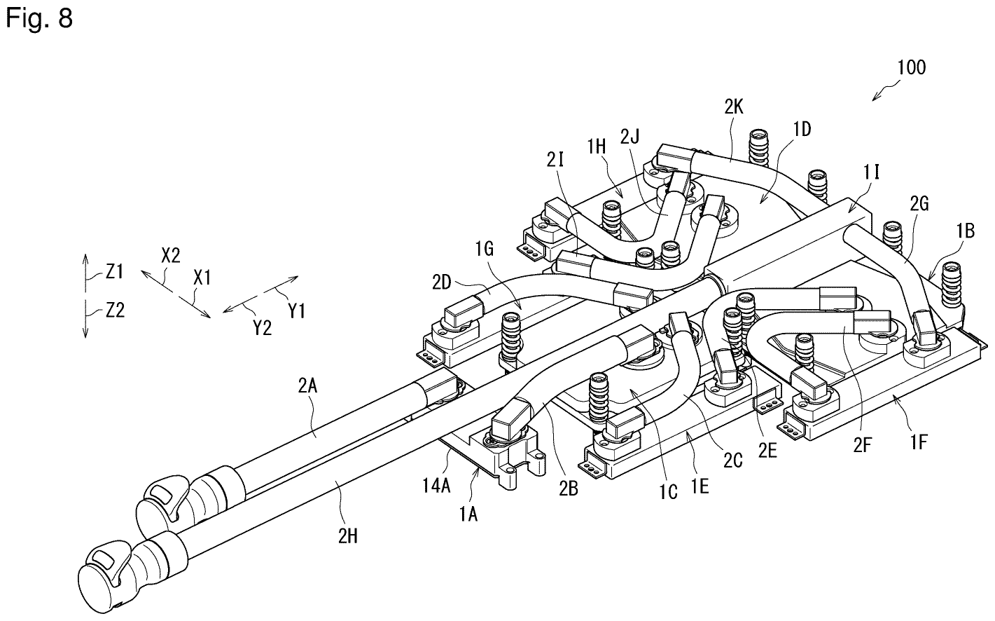

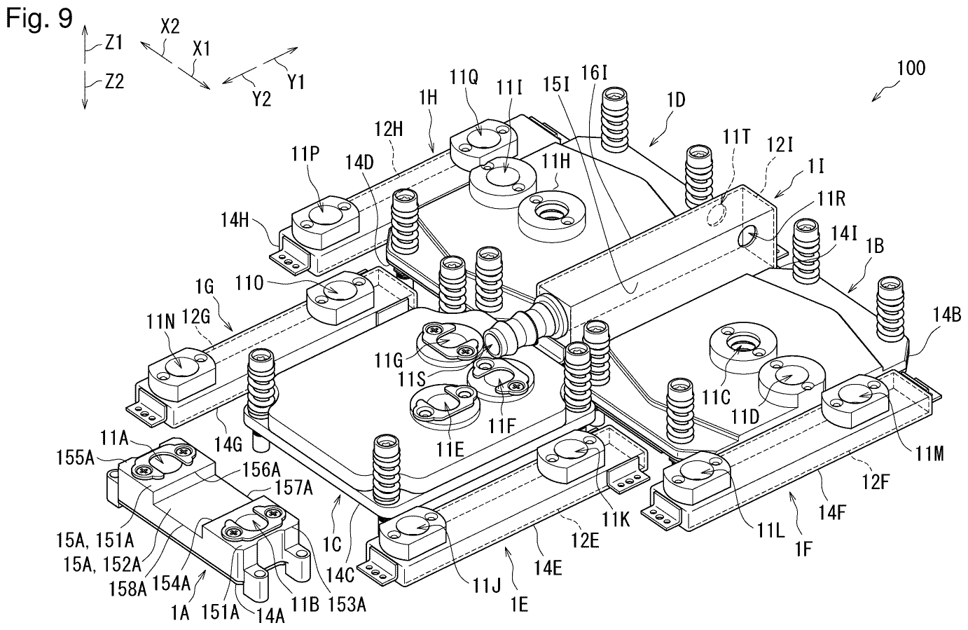

In FIGS. 8 and 9, the cooling device 100 includes cold plates 1A to 1I and pipes 2A to 2K.

In FIGS. 8 and 9, the cold plates 1A to 1D may be similar to the cold plates 1A to 1D of the first example embodiment. Accordingly, the description of the cold plates 1A to 1D is simplified.

The cold plate 1A includes openings 11A and 11B, a flow path 12A, and a cooler 14A. The cold plate 1A is an example of a “first cold plate” according to the present disclosure. The openings 11A and 11B are examples of a “first opening” and a “second opening” of the present disclosure. The flow path 12A is an example of a “first flow path” in the present disclosure.

The pipes 2A and 2B are connected to the openings 11A and 11B, respectively. The pipes 2A and 2B are examples of a “first pipe” and a “second pipe” of the present disclosure.

The cold plate 1I includes openings 11R and 11S, a flow path 12I, and a cooler 14I. The flow path 12I is continuous with each of the openings 11R and 11S. The cold plate 1I is another example of the “second cold plate” of the present disclosure. The openings 11R and 11S are other examples of the “third opening” and the “fourth opening” of the present disclosure. The flow path 12I is another example of the “second flow path” of the present disclosure.

The pipes 2G and 2H are connected to the openings 11R and 11S, respectively. The pipes 2G and 2H are examples of a “third pipe” and a “fourth pipe” of the present disclosure.

The openings 11A and 11B are located apart from each other in the X direction. The pipe 2H extends between the openings 11A and 11B and extends in the Y direction. As a result, the piping is not complicated as in the first example embodiment.

The cold plate 1C includes openings 11E to 11G, a flow path 12C (see FIGS. 5 and 6), and a cooler 14C. The cold plate 1C is another example of the “third cold plate” of the present disclosure. The openings 11E, 11F, and 11G are other examples of the “fifth opening”, the “sixth opening”, and the “seventh opening” of the present disclosure. The flow path 12C is another example of the “third flow path” of the present disclosure.

The pipes 2B to 2D are connected to the openings 11E to 11G, respectively. The pipes 2C and 2D are examples of a “fifth pipe” and an “eighth pipe” of the present disclosure.

The cold plate 1E includes openings 11J and 11K, a flow path 12E, and a cooler 14E. The flow path 12E is continuous with each of the openings 11J and 11K. The cold plate 1E is an example of a “fourth cold plate” of the present disclosure. The openings 11J and 11K are examples of the “eighth opening” and the “ninth opening” of the present disclosure. The flow path 12E is an example of the “fourth flow path” of the present disclosure.

In FIG. 9, the flow path 12E is indicated by a dashed hidden line. The same applies to the flow paths 12F to 12I.

The pipes 2C and 2E are connected to the openings 11J and 11K, respectively. The pipe 2E is an example of a “sixth pipe” of the present disclosure.

The cold plate 1B includes the openings 11C and 11D, the flow path 12B, and the cooler 14B. The cold plate 1B is an example of a “fifth cold plate” of the present disclosure. The openings 11C and 11D are examples of a “tenth opening” and an “eleventh opening” of the present disclosure. The flow path 12B is an example of a “fifth flow path” of the present disclosure.

The pipes 2E and 2F are connected to the openings 11C and 11D, respectively. The pipe 2F is an example of a “seventh pipe” of the present disclosure.

The cold plate 1F includes openings 11L and 11M, the flow path 12F, and a cooler 14F. The flow path 12F is continuous with each of the openings 11L and 11M. The cold plate 1F is an example of a “sixth cold plate” of the present disclosure. The openings 11L and 11M are examples of a “twelfth opening” and a “thirteenth opening” of the present disclosure. The flow path 12F is an example of a “sixth flow path” of the present disclosure.

The pipes 2F and 2G are connected to the openings 11L and 11M, respectively.

The cold plate 1G includes openings 11N and 11O, a flow path 12G, and a cooler 14G. The flow path 12G is continuous with each of the openings 11N and 11O. The cold plate 1G is an example of a “seventh cold plate” of the present disclosure. The openings 11N and 11O are examples of a “fourteenth opening” and a “fifteenth opening” of the present disclosure. The flow path 12G is an example of a “seventh flow path” of the present disclosure.

The pipes 2D and 2I are connected to the openings 11N and 11O, respectively. The pipe 2I is an example of a “ninth pipe” of the present disclosure.

The cold plate 1D includes openings 11H and 11I, a flow path 12D (see FIGS. 5 and 6), and a cooler 14D. The cold plate 1D is an example of an “eighth cold plate” of the present disclosure. The openings 11H and 11I are examples of a “sixteenth opening” and a “seventeenth opening” of the present disclosure. The flow path 12D is an example of an “eighth flow path” of the present disclosure.

The pipes 2I and 2J are connected to the openings 11H and 11I, respectively. The pipe 2J is an example of a “tenth pipe” of the present disclosure.

The cold plate 1H includes openings 11P and 11Q, a flow path 12H, and a cooler 14H. The flow path 12H is continuous with each of the openings 11P and 11Q. The cold plate 1H is an example of a “ninth cold plate” of the present disclosure. Openings 11P and 11Q are examples of an “eighteenth opening” and a “nineteenth opening” of the present disclosure. The flow path 12H is an example of a “ninth flow path” in the present disclosure.

The pipe 2J is connected to the opening 11P.

The cold plate 1I further includes an opening 11T. The flow path 12I is continuous with each of the openings 11R to 11T. The opening 11T is an example of a “twentieth opening” of the present disclosure.

The pipe 2K is connected to the openings 11O and 11T. The pipe 2K is an example of an “eleventh pipe” of the present disclosure.

The coolers 14E to 14I are surfaces that can be in thermal contact with an object to be cooled (not illustrated), similarly to the coolers 14A to 14D.

According to the cooling device 100 of the second example embodiment, it is possible to cool many objects to be cooled. Specifically, in FIG. 8, in the cooling device 100 in a use state, the refrigerant flows into the cold plates 1A and 1C in this order, and then flows into each of the cold plates 1E and 1G. The refrigerant flows into the cold plates 1E, 1B, 1F, and 1I in this order. The refrigerant flows into the cold plates 1G, 1D, 1H, and 1I in this order. The refrigerant joins in the cold plate 1I and flows out of the cooling device 100 via the pipe 2H.

While the refrigerant flows through the flow paths 12A to 12I, heat is transferred from an object to be cooled that is in thermal contact with the coolers 14A to 14I to the refrigerant flowing through the flow paths 12A to 12I. As a result, the object to be cooled is cooled.

The refrigerant flowing out of the cold plate 1A flows into the cold plate 1C from the opening 11C through the pipes 2B and 2E. The refrigerant flows out of the openings 11F and 11G through the flow path 12C from the opening 11E. In the course of the refrigerant flowing through the flow path 12C, the object to be cooled that is in thermal contact with the cooler 14C is cooled.

The refrigerant flowing out of the opening 11F flows into the cold plate 1B from the opening 11C through the pipes 2C and 2F. The refrigerant flows out of the opening 11D from the opening 11C through the flow path 12B. In the course of the refrigerant flowing through the flow path 12B, the object to be cooled that is in thermal contact with the cooler 14B is cooled.

The refrigerant flowing out of the opening 11G flows into the cold plate 1D from the opening 11H through the pipes 2G and 2H. The refrigerant flows out of the opening 11I through the flow path 12D from the opening 11H. In the course of the refrigerant flowing through the flow path 12D, the object to be cooled that is in thermal contact with the cooler 14D is cooled.

The high-temperature refrigerant flowing out of the opening 11D circulates in the pipe 2D. The high-temperature refrigerant flowing out of the opening 11I merges with the refrigerant flowing in the pipe 2D through the pipe 2I. The refrigerant flowing through the pipe 2D flows out of the cooling device 100.

The cold plates 1E to 1H have the same shape. The cooling device 100 can be manufactured at low cost.

At least one of the pipes 2B to 2G and 2I to 2K is curved. As a result, the pipe becomes longer than the case where the pipe is not curved. This increases the degree of freedom in layout of the cold plates 1A to 1I.

The cold plates 1B and 1D are spaced in the X direction. The X direction is an example of a “third direction” of the present disclosure. The cold plate 1I is positioned between the cold plates 1B and 1D in the X direction. This facilitates routing of the pipe 2H.

The cold plate 1I includes a first surface 15I and a second surface 16I that are separated from each other in the X direction. The openings 11R and 11T are formed in the first surface 15I and the second surface 16I, respectively. It is easy to align the lengths of the pipes 2G and 2K.

Each of the pipes 2G and 2K is curved. The tube is longer than when not curved. This increases the degree of freedom in layout of the cold plates 1I, 1B, and 1D.

As illustrated in FIGS. 1 to 6, in the main body 13C of the cold plate 1C, the three openings 11E to 11G are formed in parts other than the cooler 14 C. The number of openings may be three or more. Accordingly, the cold plate 1C has a function of a T-shaped pipe (T-joint). As a result, the number of T-shaped pipes can be reduced in the cooling device 100.

The refrigerant flows into the flow path 12 C through at least one opening 11E among the openings 11E to 11G. The refrigerant flows out of the flow path through the remaining openings 11F and 11G among the openings 11E to 11G. Accordingly, the cold plate 1C can have a function as a branch pipe.

The refrigerant may flow into the flow path 12C through a plurality of openings among the openings 11E to 11G, and the refrigerant may flow out of the flow path 12C through the remaining openings. Accordingly, the cold plate 1C can have a function as a junction pipe.

The example embodiments of the present disclosure are described above with reference to the drawings. However, the present disclosure is not limited to the above example embodiments, and can be implemented in various modes without departing from the gist of the present disclosure. Further, a plurality of constituent elements disclosed in the above example embodiments can be appropriately modified. For example, a certain constituent element of all constituent elements illustrated in a certain example embodiment may be added to constituent elements of another example embodiment, or some constituent elements of all constituent elements illustrated in a certain example embodiment may be removed from the example embodiment.

The drawings schematically show each component mainly in order to facilitate understanding of the present disclosure, and the thickness, length, number, interval, and the like of each component that is shown may be different from the actual ones for convenience of the drawings. The configuration of each component shown in the above example embodiments is an example and is not particularly limited, and it goes without saying that various modifications can be made without substantially departing from the effects of the present disclosure.

(1) In the first example embodiment, a large number of fins protrude from an end surface on the other side Z2 in the Z direction in the flow path 12A. As a result, in the cooling device 100 in a use state, when the low-temperature refrigerant flows in the flow path 12A, the efficiency of heat exchange between the refrigerant flowing in the flow path 12A and a high-temperature object to be cooled that is in thermal contact with the cooler 14A is improved. The same applies to the other flow paths 12B to 12D of the first example embodiment and the flow paths 12A to 12I of the second example embodiment.

(2) In the first example embodiment, the elbow 21A is attached to the main body 13A through the opening 11A so as to be rotatable in the circumferential direction in the Z direction on the surface 15A. As a result, the degree of freedom of the layout of the cooling device 100 with respect to an object to be cooled is improved. The same applies to the other elbows 21B, 22B, 21C, 22C, 21G, and 22G of the first example embodiment. The same also applies to the second example embodiment.

(3) Heat grease may be applied to a portion of or the entire area of the cooler 14A. The heat grease is grease having high thermal conductivity. This facilitates heat dissipation from the object to be cooled. The same applies to the other coolers 14B to 14D of the first example embodiment and the coolers 14A to 14I of the second example embodiment.

In the present disclosure, the following supplementary notes are added. The supplementary notes do not limit the refrigerant circulation devices according to example embodiments of the present disclosure.

(1) A cooling device including a first cold plate including a first opening, a second opening, and a first flow path continuous with each of the first opening and the second opening, a first pipe connected to the first opening, a second pipe connected to the second opening, a second cold plate including a third opening, a fourth opening, and a second flow path continuous with each of the third opening and the fourth opening, a third pipe connected to the third opening, and a fourth pipe connected to the fourth opening, wherein the first opening and the second opening are spaced apart from each other in a first direction, and the fourth pipe extends between the first opening and the second opening and extends in a second direction intersecting the first direction.

(2) The cooling device according to (1), further including a third cold plate including a fifth opening to which the second pipe is connected, a sixth opening to which the third pipe is connected, a seventh opening, and a third flow path continuous with each of the fifth opening, the sixth opening, and the seventh opening, a fifth pipe connected to the seventh opening, a fourth cold plate including an eighth opening to which the fifth pipe is connected, a ninth opening, and a f fourth flow path continuous with each of the eighth opening and the ninth opening; and a sixth pipe connected to the ninth opening and the fourth pipe.

(3) The cooling device according to (2), wherein at least a portion of the fourth pipe extends along at least one of the second pipe, the third pipe, and the fifth pipe.

(4) The cooling device according to (2) or (3), wherein the fifth opening, the sixth opening, and the seventh opening are spaced apart from each other in at least one of the first direction and the second direction, and the fourth pipe extends between two openings selected from the fifth opening, the sixth opening, and the seventh opening.

(5) The cooling device according to any one of (2) to (4), wherein the third opening is located farther from the sixth opening than the fourth opening, and the eighth opening is located farther from the seventh opening than the ninth opening.

(6) The cooling device according to any one of (1) to (5), further including a third cold plate including a fifth opening to which the second pipe is connected, a sixth opening, a seventh opening, and a third flow path continuous with each of the fifth opening, the sixth opening, and the seventh opening, a fifth pipe connected to the sixth opening, a fourth cold plate including an eighth opening to which the fifth pipe is connected, a ninth opening, and a fourth flow path continuous with each of the eighth opening and the ninth opening, a sixth pipe connected to the ninth opening, a fifth cold plate including a tenth opening to which the sixth pipe is connected, an eleventh opening, and a fifth flow path continuous with each of the tenth opening and the eleventh opening, a seventh pipe connected to the eleventh opening, a sixth cold plate including a twelfth opening to which the seventh pipe is connected, a thirteenth opening to which the third pipe is connected, and a sixth flow path continuous with each of the twelfth opening and the thirteenth opening, an eighth pipe connected to the seventh opening, and a seventh cold plate including a fourteenth opening to which the eighth pipe is connected, a fifteenth opening, and a seventh flow path continuous with each of the fourteenth opening and the fifteenth opening, a ninth pipe connected to the fifteenth opening, and an eighth cold plate including a sixteenth opening to which the ninth pipe is connected, a seventeenth opening, and an eighth flow path continuous with each of the sixteenth opening and the seventeenth opening, a tenth pipe connected to the seventeenth opening, a ninth cold plate including an eighteenth opening to which the tenth pipe is connected, a nineteenth opening, and a ninth flow path continuous with each of the eighteenth opening and the nineteenth opening, and an eleventh pipe connected to the nineteenth opening; wherein the second cold plate includes a twentieth opening connected to the eleventh pipe, and the second flow path is continuous with the twentieth opening.

(7) The cooling device according to (6), wherein the fourth cold plate, the sixth cold plate, the seventh cold plate, and the ninth cold plate have a same shape.

(8) The cooling device according to (6) or (7), wherein at least one of the second pipe, the third pipe, and the fifth to eleventh pipes is curved.

(9) The cooling device according to any one of (6) to (8), wherein the fifth cold plate and the eighth cold plate are spaced from each other in a third direction, and the second cold plate is located between the fifth cold plate and the eighth cold plate in the third direction.

(10) The cooling device according to any one of (6) to (9), wherein the second cold plate includes a first surface and a second surface that are spaced apart from each other in the third direction, and the third opening and the twentieth opening are defined on the first surface and the second surface, respectively.

(11) The cooling device according to any one of (6) to (10), wherein each of the third pipe and the eleventh pipe is curved.

(12) A cold plate including a main body including a cooler that is brought into thermal contact with an object to be cooled, three or more openings defined in a portion other than the cooler in the main body, and a flow path continuous to each of the three or more openings.

(13) The cold plate according to (12), wherein refrigerant flows into the flow path through at least one of the three or more openings, and the refrigerant flows out of the flow path through remaining openings.

(14) The cold plate according to (12), wherein refrigerant flows into the flow path through a plurality of openings among the three or more openings, and the refrigerant flows out of the flow path through remaining openings.

The cooling device according to the present disclosure has industrial applicability.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a first cold plate including a first opening, a second opening, and a first flow path continuous with each of the first opening and the second opening;
a first pipe connected to the first opening;
a second pipe connected to the second opening;
a second cold plate including a third opening, a fourth opening, and a second flow path continuous with each of the third opening and the fourth opening;
a third pipe connected to the third opening; and
a fourth pipe connected to the fourth opening; wherein
the first opening and the second opening are spaced apart from each other in a first direction; and
the fourth pipe extends between the first opening and the second opening and in a second direction intersecting the first direction.

2. The cooling device according to claim 1, further comprising:
a third cold plate including a fifth opening to which the second pipe is connected, a sixth opening to which the third pipe is connected, a seventh opening, and a third flow path continuous with each of the fifth opening, the sixth opening, and the seventh opening;
a fifth pipe connected to the seventh opening;
a fourth cold plate including an eighth opening to which the fifth pipe is connected, a ninth opening, and a fourth flow path continuous with each of the eighth opening and the ninth opening; and
a sixth pipe connected to the ninth opening and the fourth pipe.

3. The cooling device according to claim 2, wherein at least a portion of the fourth pipe extends along at least one of the second pipe, the third pipe, and the fifth pipe.

4. The cooling device according to claim 2, wherein
the fifth opening, the sixth opening, and the seventh opening are spaced apart from each other in at least one of the first direction and the second direction; and
the fourth pipe extends between two openings selected from the fifth opening, the sixth opening, and the seventh opening.

5. The cooling device according to claim 2, wherein
the third opening is located farther from the sixth opening than the fourth opening; and
the eighth opening is located farther from the seventh opening than the ninth opening.

6. The cooling device according to claim 1, further comprising:
a third cold plate including a fifth opening to which the second pipe is connected, a sixth opening, a seventh opening, and a third flow path continuous with each of the fifth opening, the sixth opening, and the seventh opening;
a fifth pipe connected to the sixth opening;
a fourth cold plate including an eighth opening to which the fifth pipe is connected, a ninth opening, and a fourth flow path continuous with each of the eighth opening and the ninth opening;
a sixth pipe connected to the ninth opening;
a fifth cold plate including a tenth opening to which the sixth pipe is connected, an eleventh opening, and a fifth flow path continuous with each of the tenth opening and the eleventh opening;
a seventh pipe connected to the eleventh opening;
a sixth cold plate including a twelfth opening to which the seventh pipe is connected, a thirteenth opening to which the third pipe is connected, and a sixth flow path continuous with each of the twelfth opening and the thirteenth opening;
an eighth pipe connected to the seventh opening; and
a seventh cold plate including a fourteenth opening to which the eighth pipe is connected, a fifteenth opening, and a seventh flow path continuous with each of the fourteenth opening and the fifteenth opening;
a ninth pipe connected to the fifteenth opening; and
an eighth cold plate including a sixteenth opening to which the ninth pipe is connected, a seventeenth opening, and an eighth flow path continuous with each of the sixteenth opening and the seventeenth opening;
a tenth pipe connected to the seventeenth opening;
a ninth cold plate including an eighteenth opening to which the tenth pipe is connected, a nineteenth opening, and a ninth flow path continuous with each of the eighteenth opening and the nineteenth opening; and
an eleventh pipe connected to the nineteenth opening; wherein
the second cold plate includes a twentieth opening connected to the eleventh pipe; and
the second flow path is continuous with the twentieth opening.

7. The cooling device according to claim 6, wherein the fourth cold plate, the sixth cold plate, the seventh cold plate, and the ninth cold plate have a same shape.

8. The cooling device according to claim 6, wherein at least one of the second pipe, the third pipe, and the fifth to eleventh pipes is curved.

9. The cooling device according to claim 6, wherein
the fifth cold plate and the eighth cold plate are spaced from each other in a third direction; and
the second cold plate is located between the fifth cold plate and the eighth cold plate in the third direction.

10. The cooling device according to claim 9, wherein
the second cold plate includes a first surface and a second surface that are spaced apart from each other in the third direction; and
the third opening and the twentieth opening are located on the first surface and the second surface, respectively.

11. The cooling device according to claim 10, wherein each of the third pipe and the eleventh pipe is curved.

12. A cold plate comprising:
a main body including a cooler that is brought into thermal contact with an object to be cooled;
three or more openings in a portion other than the cooler in the main body; and
a flow path continuous to each of the three or more openings.

13. The cold plate according to claim 12, wherein refrigerant flows into the flow path through at least one of the three or more openings, and the refrigerant flows out of the flow path through remaining openings.

14. The cold plate according to claim 12, wherein refrigerant flows into the flow path through a plurality of openings among the three or more openings, and the refrigerant flows out of the flow path through remaining openings.
